(19) United States
(12) Patent Application Publication
(10) Pub. No.: US 2023/0205837 A1
(43) Pub. Date: Jun. 29, 2023

(54) METHODS OF COMMUNICATION AVOIDANCE IN PARALLEL SOLUTIONS OF PARTIAL DIFFERENTIAL EQUATIONS

(71) Applicant: Advanced Micro Devices, Inc., Santa Clara, CA (US)

(72) Inventors: Laurent S. White, Austin, TX (US); Ganesh Dasika, Austin, TX (US); Saketh Venkata Rama, Wakefield, MA (US)

(21) Appl. No.: 17/561,227

(22) Filed: Dec. 23, 2021

(51) Int. Cl. G06F 17/13; G06N 20/00; G01R 33/24

(52) U.S. Cl. CPC G06F 17/13; G06N 20/00; G01R 33/24

(57) ABSTRACT

A physical system is simulated using a model including a plurality of elements in a mesh or grid. The elements are divided into partitions processed by different processing units. For some time steps, flux data is transmitted between partitions for updating the state of edge elements of the partitions. Periodically, transmission of flux data is suppressed and flux data is obtained by linear interpolation based on past flux data. Alternatively, flux data is obtained by processing state variables of an edge element and past flux data using a machine learning model, such as a DNN.

### BACKGROUND

Many scientific problems may be modeled by partial differential equations. Electromagnetic fields may be approximated using the Maxwell's equations. Propagation of acoustic waves may be modeled using the acoustic wave equation. Fluid dynamics may be modeled using the Navier-Stokes equation. All of these equations include partial derivatives of multiple variables. Nearly every field of science and technology relies on some form of partial differential equations to model physical systems.

Inasmuch as closed form solutions to these equations do not exist for a typical physical system, they are modeled by discretizing the physical system into a grid or mesh of elements that each have one or more variables describing the state of each element. At each time step, the state of an element is updated based on its current state and the state of adjacent elements at the previous time step. For purpose of this application, the contribution of each neighboring element to the state of the element is referred to as “flux.” The flux for a given physical system may represent the transmission of pressure, electromagnetic fields, force, momentum, or some other modeled phenomenon.

Referring to FIG. 1, a physical system may be modeled by many thousands, millions, or more elements, represented by the illustrated triangles. Such models cannot possibly be stored in the memory of a single computer and updating each element at each time step cannot be performed in a timely manner by a single processor. Accordingly, the model may be divided into partitions, P0-P4 in the illustrated example. Each partition P0-P4 includes a set of contiguous elements. Each partition P0-P4 may be processed by a separate processing unit. The processing units may include processing cores of a multi-core processor or graphics processing unit (GPU). The processing units may be distributed across multiple computing devices coupled to one another by a backplane of a common chassis or a network.

The state S1 of an element of partition P2 cannot be updated until the flux data F has been received from the neighboring element of partition P3. The flux data F is computed based on the state S2 of the neighboring element, which is not stored in the memory of the same processing unit that stores state S1. The process of preparing and transmitting the flux data F between processing units adds significant delay to updating the elements of the model at each time step.

Referring to FIG. 2A, the flux data F is packed 200 by the processing unit hosting partition P3 and transfer to the processing unit hosting partition P2 is initiated. Packing may include compressing and/or packaging the flux data F into a message passing interface (MPI) message. The flux data from some or all elements of partition P3 on the boundary between partitions P2 and P3 may be included in the message. The flux data message is then transferred 202. The processing unit hosting partition P2 receives and unpacks 204 the flux data message to obtain the flux data F. The processing unit hosting partition P2 then performs 206 local calculations, i.e., updating the state of elements that are not adjacent to the elements of another partition. This may include calculating flux between neighboring elements within the partition P2. The processing unit hosting partition P2 may also perform 208 edge calculations whereby the states of edge elements neighboring other partitions are updated using the flux data received in messages from the neighboring partition. In the illustrated example, this includes updating state S1 using the flux data F received for partition P3. In some implementations, performing 208 neighbor calculations further includes calculating flux values for use in the next time step. Flux values are calculated for the next time step for one or both of edge elements and non-edge elements of each partition.

Referring to FIG. 2B, some improvement is obtained by performing 206 the local calculations during transfer 202 of the flux data message inasmuch as these calculations do not rely on flux data from neighboring partitions. As is represented in FIG. 2B, the time required to perform 206 the local calculations is typically much less than the time required to transfer 202 and unpack 204 the flux data message. This limits the amount of time that can be saved using this approach. Since the time spent performing local calculations is small relative to the time spent transferring 202 flux data, there is often little benefit to improving the performance of a kernel defining the calculations.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

In the drawings:

FIG. 1 is a schematic representation of a mesh divided into partitions for processing by separate processing units in accordance with the prior art;

FIG. 2A is a timing diagram illustrating the processing of elements and transmission of flux data in accordance with the prior art;

FIG. 2B is a timing diagram illustrating an alternative approach for processing elements and transmitting flux data in accordance with the prior art;

FIG. 3 is a process flow diagram of a method for reducing transmission of flux data in accordance with an implementation of the present invention.

FIG. 4A is a plot of flux values for an element over time;

FIG. 4B is a plot illustrating variation in a flux value within a given element over time with and without extrapolation in accordance with an implementation of the present invention.

FIG. 5 is a schematic block diagram of a machine learning approach for predicting flux data in accordance with an implementation of the present invention;

FIG. 6A is a timing diagram illustrating the processing of elements and transmission of flux data for multiple time steps in accordance with the prior art;

FIG. 6B is a timing diagram illustrating the processing of elements with periodic suppression of transmission of flux data in accordance with an implementation of the present invention;

FIG. 7 is a parity plot of actual flux values with respect to flux values predicted in accordance with an implementation of the present invention;

FIG. 8A is a surface plot of a state variable of elements of a model obtained using communication of flux values at every time step;

FIG. 8B is a surface plot of a state variable of elements of a model obtained with suppression of communication of flux values at every other time step in accordance with an implementation of the present invention;

FIG. 9A is a surface plot of a state variable of a model having parameters identical to those used to train a machine learning model used to estimate flux values;

FIG. 9B is a surface plot of a state variable of a model having parameters different from those used to train the machine learning model used to estimate flux values; and

FIG. 10 is a schematic block diagram of a computing device that may be used to implement the system and methods described herein.

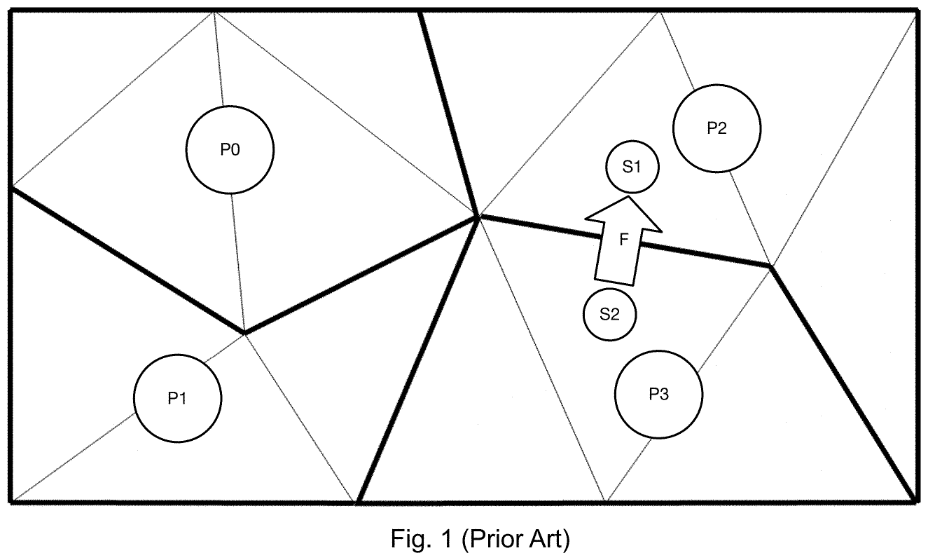

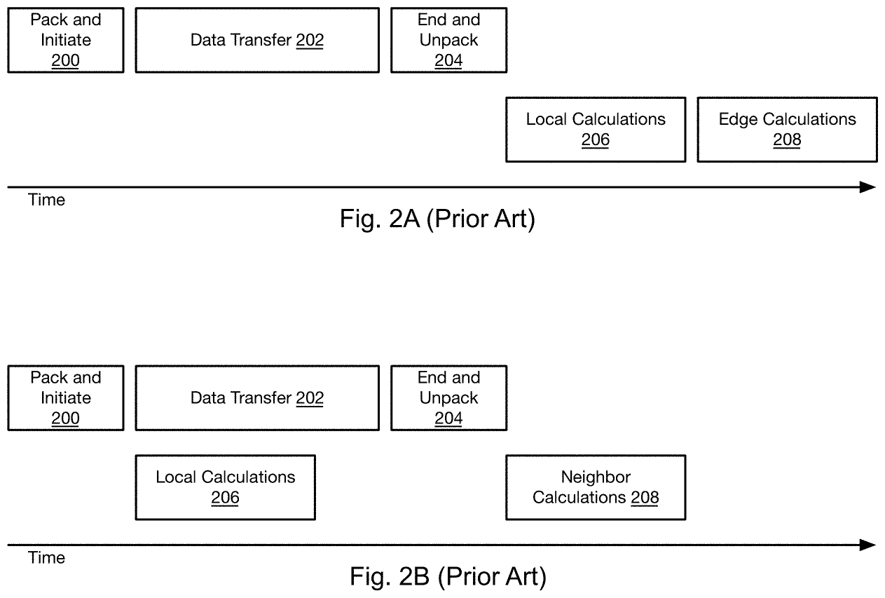

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

### General Overview

A physical system is modeled by a mesh or grid of elements that are divided into partitions. Each partition is processed by a different processing unit. The state of the system over time is modeled by updating each element at each time step of a plurality of discrete time steps. Each element is updated based on the current state of the element and flux data from neighboring elements. Periodically, transmission of flux data between processing units hosting neighboring partitions is suppressed. Flux data for neighboring partitions is estimated by extrapolating from past flux values, such as flux values from two or more preceding time steps. In an alternative approach, flux data is estimated using a machine learning model trained to estimate flux data for the physical system. In this manner, processing times are reduced by at least partially eliminating data transmission between processing units.

### Estimating Flux Data Using Extrapolation

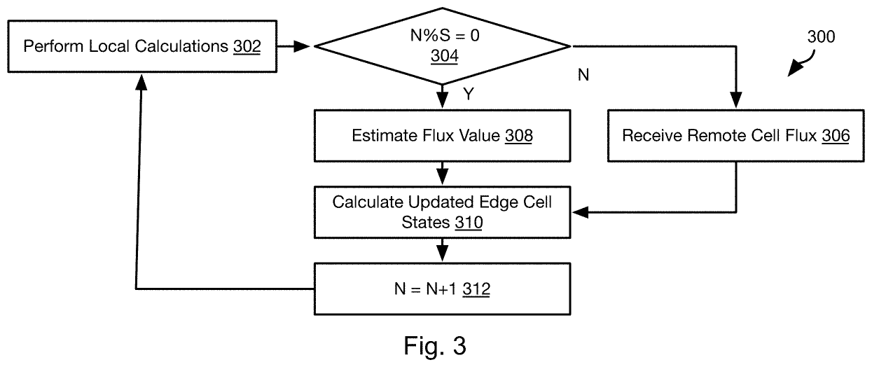

FIG. 3 illustrates a method 300 that is used to extrapolate flux data. The method 300 is performed by a processing unit (“the local processing unit”) hosting a partition (“the local partition”) with communication with another processing unit (“the remote processing unit”) hosting another partition (“the remote partition”). The method 300 is performed by the local processing unit with respect to any number of remote processing units and remote partitions. The method 300 is capable of being used for a two-dimensional system, three-dimensional system, or systems modeled using a greater number of dimensions.

For some physical systems, the method 300 is preceded by initializing state variables of elements of the model for all partitions. In particular, the state variables of one or more elements may be set to initial conditions of the physical system being modeled. The state variables of elements of the boundary of the model of the physical system are also set to boundary conditions where this is part of the physical system being modeled.

State variables are referred to in the plural in the examples discussed herein. However, a single state variable is usable without modifying the approach described herein. In some implementations, the state of an element is represented by values for the state variables as well as one or more partial derivatives of one or more of the state variables. Partial derivatives include first order and/or higher order derivatives.

The method 300 includes performing 302 local calculations. Performing 302 local calculations includes calculating flux between non-edge elements of the local partition and updating the state variables of the non-edge elements using the flux and current values of the state variables. The manner in which the flux is calculated and the state variables are updated is according to the physical system being modeled and is performed using any modeling approach known in the art.

The method 300 includes evaluating 304 whether the index (N) of the current time step corresponds to a time step in which communication of flux data between the local processing unit and the remote processing unit is to be suppressed. For example, in some implementations, one time step out of every S time steps is suppressed, where S is an integer greater than one. For example, S=3 results in communication being suppressed every third time step. In some implementations, the evaluation 304 includes evaluating whether N % S is equal to zero, where % is the modulus operator. Other values of S may be used, such as 2, in order to suppress transmission on every other time step. Other more complex repeating patterns may be used to determine whether transmission is to be suppressed. For example, a repeating pattern may be defined as transmit for Q steps and suppress for R steps, where one or both of Q and R are greater than one. In some implementations, suppression of transmission does not begin until N is greater than a threshold value that is greater than S.

If communication is not suppressed, the method 300 includes receiving 306 remote flux data from the remote processing unit, each item of flux data corresponding to one of the edge elements of the remote partition adjoining the edge elements of the local partition. In some implementations, the remote flux data may be received in the form of a MPI message. If communication is suppressed, the method 300 includes estimating 308 flux values for each edge element. In a first example discussed herein, estimating 308 includes performing extrapolation based on past flux values. For example, where F(N−2) and F(N−1) are the flux values for a particular edge element of the local partition from the time steps preceding the current time step N, F(N) for the edge element may be calculated as a linear extrapolation of F(N−2) and F(N−1). For example, the point (N, F(N)) is calculated such that it lies on a line passing through points (N−2, F(N−2)) and (N−1, F(N−1)). In some implementations, more points are used. For example, where three points are used, a quadratic extrapolation may be performed. This results in a 33 percent reduction in data transmission requirements.

For either outcome of the evaluation 304, updated states of the edge cells of the local partition are calculated 310 using either the remote flux data from step 306 or the extrapolated flux data from step 308 and current values of the state variables of the edge cells. The time step index is then incremented 312 and the method 300 repeats at step 302.

### Experimental Results

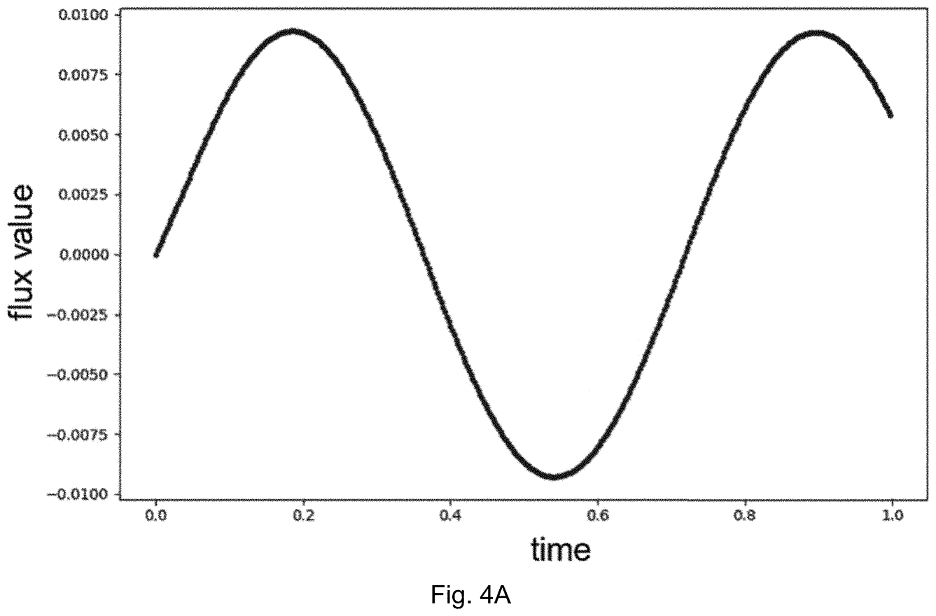

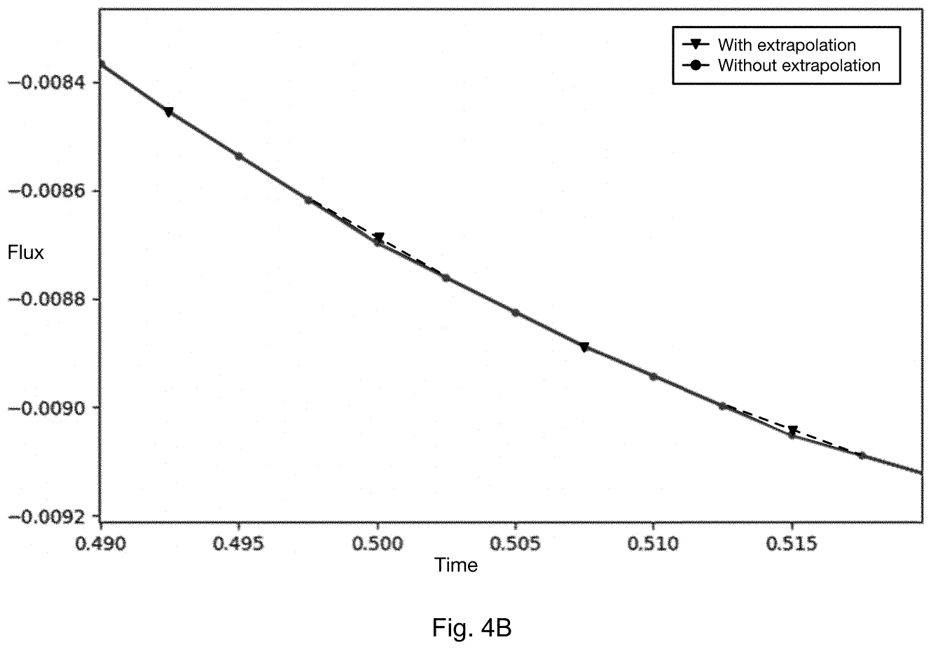

FIG. 4A is a plot of actual values of flux into an element in a model of a physical system modeling acoustic wave propagation. FIG. 4B is a plot of actual transmitted flux (without extrapolation) as compared to flux including both transmitted and extrapolated flux. In the illustrated plot, extrapolation is performed every third time step. As is apparent, there is a discernible error for some extrapolated values. However, the plot of FIG. 4B shows that the model has numerical stability and the non-extrapolated flux values do not have discernible accumulated error due to errors in preceding extrapolated values.

In the illustrated examples, the state variables of each cell are p (pressure), u (particle velocity in the x direction), and v (particle velocity in the y direction). Table 1 lists errors in the state variables following 200 time steps for modeling with transmission of flux data and modeling with periodic suppression of transmission of flux data on every third time step. As is apparent, the accuracy is the same up to the third digit of precision.

TABLE 1
Error Values

| | Error with | Error with Suppression of |
|---|---|---|
| Variable | Transmission | Transmission (1 in 3) |
| p | 1.787874 × 10⁻² | 1.786047 × 10⁻² |
| u | 1.412958 × 10⁻² | 1.414311 × 10⁻² |
| v | 1.412959 × 10⁻² | 1.414312 × 10⁻² |

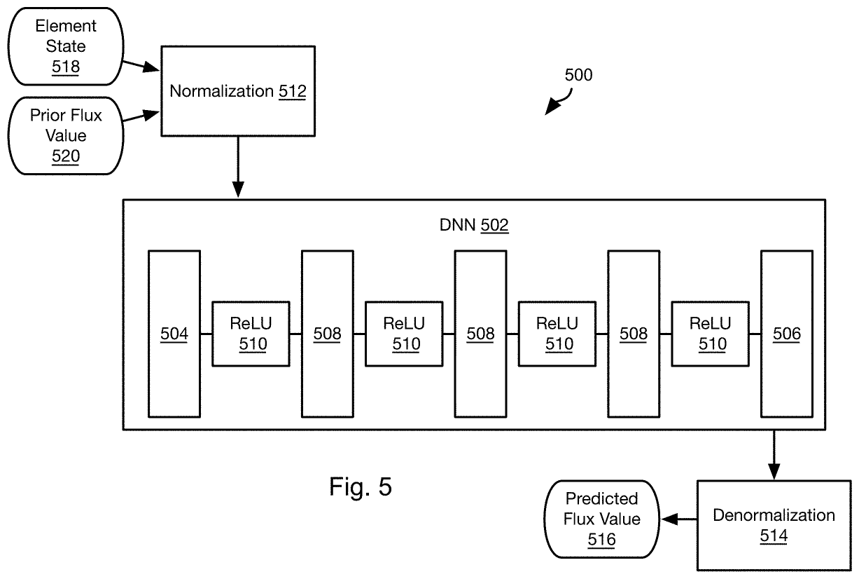

FIG. 5 illustrates a system 500 that makes use of machine learning to facilitate suppression of transmission of flux data. For example, the system 500 is used at step 308 in some implementations of the method 300 to estimate flux values. The system 500 includes a machine learning model, which is a deep neural network (DNN) 502 in the illustrated example. Other types of neural networks such as recurrent neural networks (RNN) or convolution neural networks (CNN) may also be used. In other implementations, the machine learning model is a genetic algorithm, Bayesian network, decision tree, or other type of machine learning model.

In the illustrated implementation, the DNN 502 includes a plurality of layers including an initial layer 504, final layer 506, and one or more hidden layers 508 between the initial layer and final layer 506. For the acoustic wave equation, 10 units per layer 504, 506, 608 and three hidden layers 508 were found to be adequate. The activation for each layer 506, 508 may be a rectified linear activation unit (ReLU) function 510. In some implementations, the DNN 502 is preceded by a normalization stage 512 and followed by a denormalization stage 514.

Inputs to the machine learning model 502 include an element state 518 and a prior flux value 520. The element state 518 includes one or more state variables. In some implementations, the element state 518 includes first order, second order, or other derivatives of one or more of the state variables. In some implementations, the element state 518 includes only values that are local to the local processing unit and includes only values that are inputs to the function used to compute the updated state of an element. The state variables and any derivatives thereof will correspond to the physical system being modeled.

For example, with transmission of flux data, the flux into an element from a neighboring element is of the form F=f(pⁱⁿ,p^{ex}), where f is a mathematical function according to the physical model, pⁱⁿ is one or more state variables of the element, and p^{ex} is one or more state variables of the neighboring element. Accordingly, the flux data transmitted from the remote processing unit to the local processing unit may be the one or more state variables of the neighboring element or some representation thereof, such as a delta with respect to a previous value of the one or more state variables.

With suppression of transmission of flux data, the machine learning model 502 may calculate the flux according to:

$$F = f ( {p}^{i n} , \frac{\partial {p}^{i n}}{dx} , \frac{\partial {p}^{i n}}{dy} , {F}_{prev} ) ,$$

where pⁱⁿ is one or more state variables for the element as calculated in the prior time step,

$$\frac{\partial {p}^{in}}{dx}$$

is one or more partial derivatives of the one or more state variables with respect to x from the prior time step,

$$\frac{\partial {y}^{in}}{dy}$$

is one or more partial derivatives of the one or more state variables with respect to y from the prior time step, and Fₚᵣₑᵥ is the flux received from the neighboring element in a prior time step. Using the example of the acoustic wave equation, the element state 518 includes such values as p,

$$\frac{\partial p}{dx} , \frac{\partial p}{dy} , \frac{\partial u}{dx} , \frac{\partial u}{dy} , \frac{\partial v}{dx} , and \frac{\partial v}{dy} .$$

In the three-dimensional case, the element state 518 may include such values as p,

$$\frac{\partial p}{dx} , \frac{\partial p}{dy} , \frac{\partial p}{dz} , \frac{\partial u}{dx} , \frac{\partial u}{dy} , \frac{\partial u}{dz} , \frac{\partial v}{dx} , \frac{\partial v}{dy} , \frac{\partial v}{dz} , \frac{\partial w}{dx} , \frac{\partial w}{dy} , and \frac{\partial w}{dz} ,$$

where w is particle velocity in the z direction.

Training of the DNN 502 is performed by generating training data entries. The training data entries are obtained by processing a model of a physical system including a grid or mesh of elements as described above. A training data entry may be generated by using the one or more state variables and flux value of an element prior to a current time step as inputs and the flux value calculated for the current time step as the desired output. Note that training data entries may be generated for any element of the model with respect to any neighboring element and need not correspond to edge elements on a boundary of a partition. Training of the DNN 502 may include using a stochastic process or other techniques to hinder overfitting.

Training using the training data entries is performed according to any approach known in the art for the machine learning model being used for the system 500. For example, for the acoustic wave model in the above-described examples, training data was generated by running a numerical simulation for 100 time steps and generating a training data entry for each element at each time step. 90 percent of the training data entries were used for training and the remainder were used for validation. Training was performed with batch sizes of 256 training data entries for 100 epochs. The reduced batch size was found to help convergence and reduce the variance of predictions. This is just an example of training. Other machine learning models for predicting flux for models of other physical system may use different sizes of batches, different number of epochs.

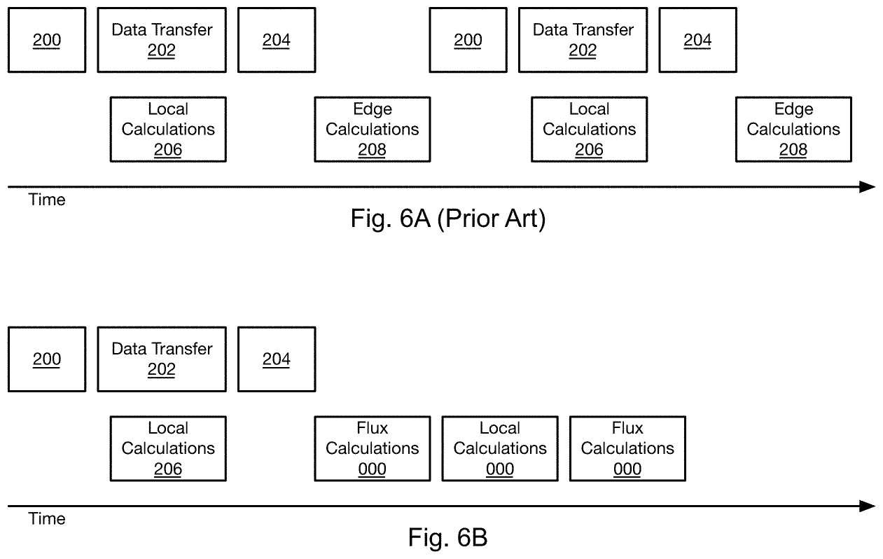

FIGS. 6A and 6B illustrate the time savings obtained using the system 500 to suppress transmission of flux data for every second time step. FIG. 6A illustrates the processing performed for two time steps without suppressing transmission of flux data. Each time step therefore includes a packing and initiation step 200, data transfer step 202, and ending and unpacking step 204. Local calculations 206 are performed concurrently with the data transfer step 202 followed by performing 208 edge calculations as described above. As shown in FIG. 6B, using the system 500, steps 200, 202, and 204 are suppressed for the second time step, enabling the edge calculations to be performed 208 sooner. Inasmuch as the delays caused by data transmission are drastically reduced, there is greater justification to improve the performance of the kernel defining the calculations for updating each element.

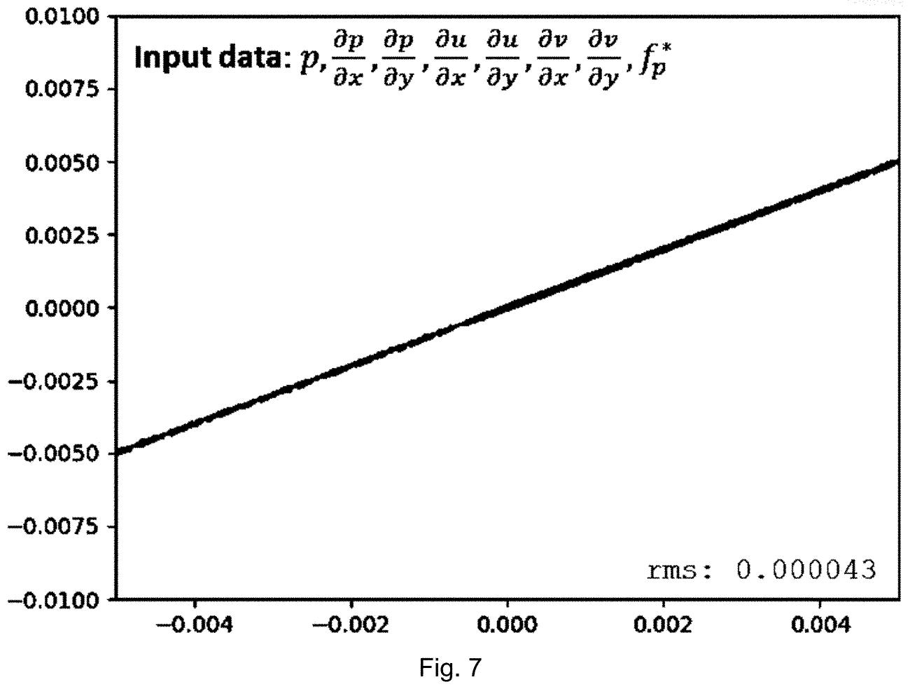

FIG. 7 is a parity graph showing predicted flux values (y axis) with respect to actual flux values (x axis) using the DNN 502 that was configured and trained as described above. The illustrated plot is actually two lines that are so close as to be indistinguishable, indicating very high accuracy. The root mean square (RMS) of the parity graph was found to be 0.000043 which indicates very high accuracy.

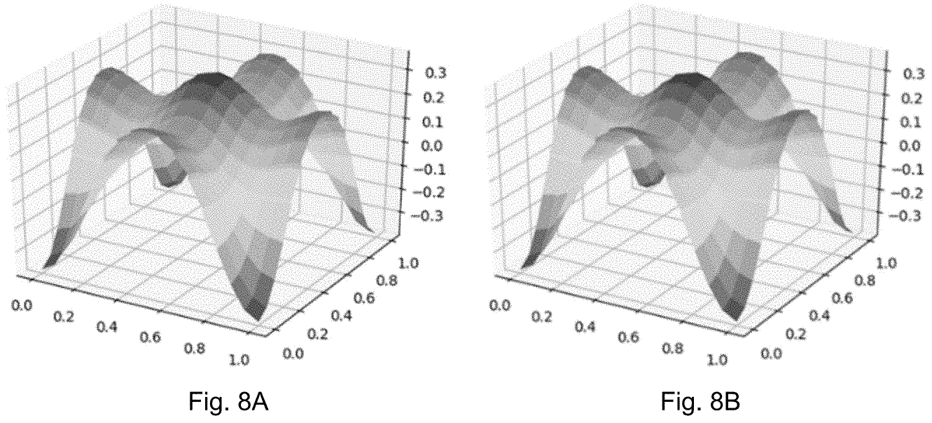

FIG. 8A is a surface plot of simulated pressure values for a model of a physical system that were obtained with transmission of flux between elements at every iteration. FIG. 8B is a surface plot of pressure values for the same model in which the flux for every element of the model (not just edge elements) was estimated using the system 500 for every other time step with the flux being calculated using data from neighboring elements for the remaining time steps. As is readily apparent, there is no visually discernible difference between the plots. Tables 2 shows the maximum and minimum values for the state variables (p, u, v) for both simulations. As is readily apparent, the system 500 was able to achieve highly accurate results. In the case of a model where the flux is only estimated using the system 500 for edge elements, the accuracy will be even greater. In Table 2, “T” indicates a simulation where transmitted flux is calculated at every time step and “S” indicates a simulation where transmitted flux is estimated using the system 500 for every other time step.

Use of the system 500 on every other time step resulted in accurate values to three or more digits of precision for all state variables. The results summarized herein were obtained using a system 500 without the normalization and denormalization stages 512, 514, which, if used, would further improve accuracy.

Since transmission of flux values was suppressed at every other time step, the transmission of flux data is reduced by 50 percent. Given the high degree of accuracy and numerical stability of the system 500, in some applications, the frequency of transmission of flux data between partitions is reduced even more, such as once every third time step, every fourth time step, or even higher values. In some applications, transmission of flux data is eliminated entirely for all time steps throughout a simulation or following a quantity of initial time steps. Where the transmission of flux data is suppressed for multiple time steps, the computation of multiple time steps becomes independent and readily processed using large arrays of processing cores, such as are available in a GPU.

TABLE 2
Values of State Variables With and Without Transmission of Flux Data

| Var. | Min T | Min S | \|Difference\| | Max T | Max S | \|Difference\| |
|---|---|---|---|---|---|---|
| p | −.385806528 | −.384880002 | 9.26 × 10⁻⁴ | .357365909 | .361351670 | 3.99 × 10⁻³ |
| u | −.151311604 | −.15410946 | 2.80 × 10⁻³ | .151311604 | .151383276 | 7.16 × 10⁻⁵ |
| v | −.151311604 | −.151395664 | 8.40 × 10⁻⁵ | .151311604 | .151442548 | 1.30 × 10⁻⁴ |

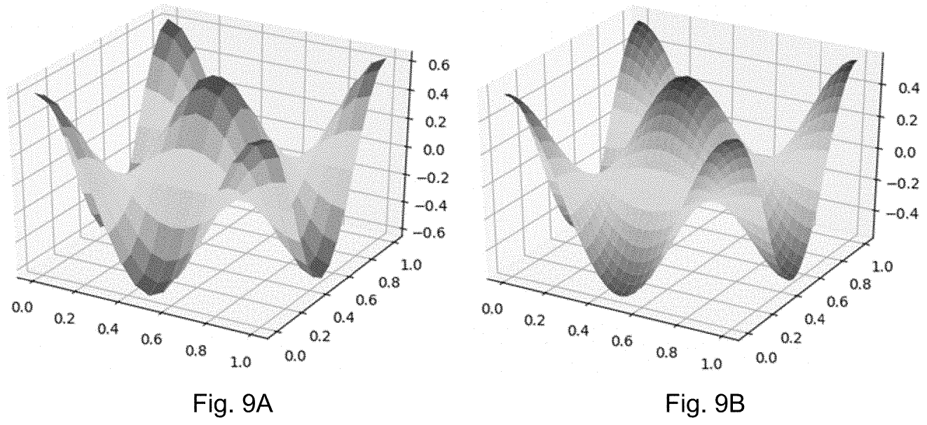

Referring to FIGS. 9A and 9B, the system 500 trained with one model of a physical system was also found to achieve a high degree of accuracy for other models of the same type of physical system. FIG. 9A represents a surface plot of pressure values obtained for a simulation using a first model configuration that is the same as that used to train the DNN 502 of the system 500. The first configuration included a first set of initial conditions, a first mesh resolution, a first polynomial degree, and first integration scheme. FIG. 9B represents a surface plot of pressure values obtained for a simulation with a second model configuration, the second model configuration including a second set of initial conditions that was different from the first set of initial conditions, a second mesh resolution that was finer than the first mesh resolution, the first polynomial degree, and a second integration scheme that was different from the first integration scheme. The simulations for both FIGS. 9A and 9B were performed with suppression of transmission of flux data for every element every second time step using the system 500.

The system 500 was found to be robust and yield accurate results (see Table 3) despite the differences between the first configuration and the second configuration. The system 500 therefore was found to accurately model a type of physical system without regard to the manner in which the model of a particular physical system of that type is defined. Table 3 further shows that the error was smaller for the finer mesh despite the different configuration, which conforms to mathematical theory that there is second order convergence as the resolution of the mesh is increased.

TABLE 3
Errors Using Machine Learning for Suppression
in Different Model Configurations

| | Error with | Error with | Error with | Error with |
|---|---|---|---|---|
| | Transmission | Suppression | Transmission | Suppression |
| Variable | (1^{st} Config.) | (1^{st} Config.) | (2^{nd} Config.) | (2^{nd} Config.) |
| p | 4.973842 × | 4.824839 × | 1.787874 × | 1,788846 × |
| | 10⁻² | 10⁻² | 10⁻² | 10⁻² |
| u | 6.004535 × | 5.622781 × | 1.412958 × | 1.270965 × |
| | 10⁻² | 10⁻² | 10⁻² | 10⁻² |
| v | 6.004535 × | 5.622851 × | 1.412959 × | 1.264351 × |
| | 10⁻² | 10⁻² | 10⁻² | 10⁻² |

Table 4 summarizes additional experimental results showing the accuracy of modeling a physical system with transmission of flux data being suppressed for some time steps. The experimental setup for the results of Table 4 included a unit cube made up of 13,824 elements distributed over eight processing units embodied as cores of a 24-core central processing unit (CPU). The physical system modeled was the propagation of acoustic waves and the acoustic wave equation was used. The geometry and initial conditions were sufficiently simple that an analytical solution was known. Errors for different modeling approaches could therefore be calculated by comparison to the analytical solution. Errors were calculated as the L2 norm of pressure error after the final time step. The scenarios listed in Table 4 include a baseline (numerical modeling with transmission of flux at every time step), extrapolation every third time step, extrapolation every second time step, estimation of flux every third time step using a neural network, and estimation of flux every other time step using the neural network.

TABLE 4
Accuracy Comparison for Multiple Scenarios

| Scenario | Error vs. Analytical Solution |
|---|---|
| Baseline | 7.54 × 10⁻⁵ |
| Extrapolation (3) | 7.54 × 10⁻⁵ |
| Extrapolation (2) | NaN (unstable) |
| Neural Network (3) | 7.53 × 10⁻⁵ |
| Neural Network (2) | 7.53 × 10⁻⁵ |

As is apparent, extrapolation every third step and using the neural network for estimation every second time step and every third time step provided the same (or better) accuracy as numerical modeling with transmission of flux every time step.

Table 5 illustrates the time savings obtained by modeling a physical system with transmission of flux data being suppressed for some time steps. The experimental setup for the results of Table 4 included the same unit cube as for the results of Table 4 but with a finer mesh of 13,824 elements distributed over 32 nodes, each node including two 64-core server-class CPUs. The columns in Table 5 include Flux (time spent calculating flux values), Comm. (MPI communication time the time), and Total (the sum of these values). Times were measured for ten runs and the average values measured for these runs are listed in Table 5, along with the standard deviation (in parentheses). All values are in units of seconds.

TABLE 5
Computation Time Comparison for Multiple Scenarios

| Scenario | Flux | Comm. | Total |
|---|---|---|---|
| Baseline | 7.60 (0.85) | 91.75 (6.45) | 131.50 (6.49) |
| Extrapolation (3) | 9.40 (0.52) | 73.02 (3.35) | 116.57 (2.43) |
| Neural Network (2) | 24.80 (0.95) | 48.16 (4.82) | 107.86 (7.42) |

As shown by the results, there were a 20 percent reduction and a 48 percent reduction in communication time when extrapolation was performed every third time step and when estimation was performed every second time step using the neural network, respectively. Table 5 further shows that where the neural network was used, the time spent computing flux values increases but not enough to offset the time savings obtained by reducing communication, resulting in an overall time savings of 18 percent relative to the baseline scenario. Hardware acceleration techniques were not used to reduce the computation time when calculating flux and therefore additional time savings are achievable.

### Hardware Overview

According to one implementation, the techniques described herein are implemented by one or more special-purpose computing devices. The special-purpose computing devices in some implementations are hard-wired to perform the techniques, or include digital electronic devices such as one or more application-specific integrated circuits (ASICs) or field programmable gate arrays (FPGAs) that are persistently programmed to perform the techniques, or include one or more general purpose hardware processors programmed to perform the techniques pursuant to program instructions in firmware, memory, other storage, or a combination. In some implementations, such special-purpose computing devices also combine custom hard-wired logic, ASICs, or FPGAs with custom programming to accomplish the techniques. The special-purpose computing devices are, in some implementations, desktop computer systems, portable computer systems, handheld devices, networking devices or any other device that incorporates hard-wired and/or program logic to implement the techniques.

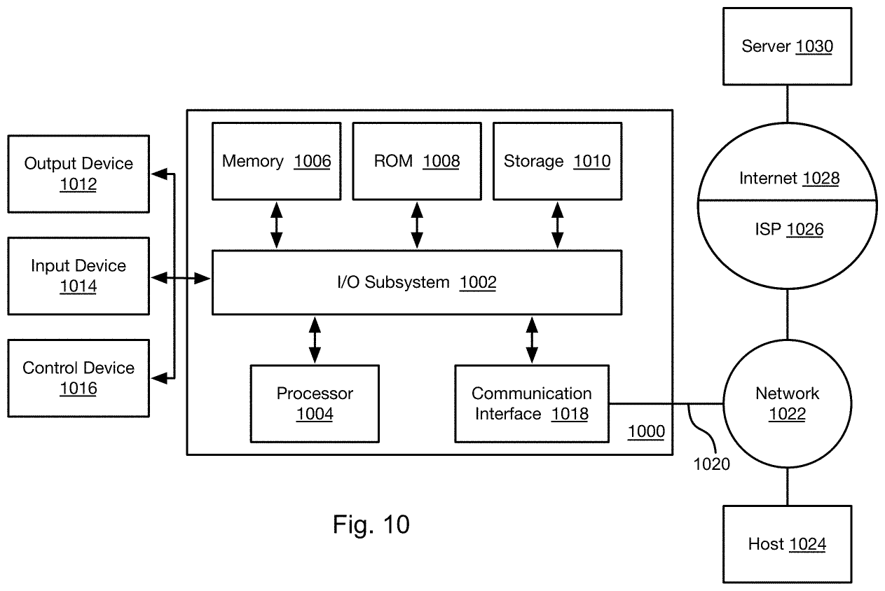

For example, FIG. 10 is a block diagram that illustrates a computer system 1000 upon which an implementation of the invention is implemented in some applications. Computer system 1000 includes a bus 1002 or other communication mechanism for communicating information, and a hardware processor 1004 coupled with bus 1002 for processing information. Hardware processor 1004 is, for example, a general purpose microprocessor.

Computer system 1000 also includes a main memory 1006, such as a random access memory (RAM) or other dynamic storage device, coupled to bus 1002 for storing information and instructions to be executed by processor 1004. Main memory 1006 is used for storing temporary variables or other intermediate information during execution of instructions to be executed by processor 1004. Such instructions, when stored in non-transitory storage media accessible to processor 1004, render computer system 1000 into a special-purpose machine that is customized to perform the operations specified in the instructions.

Computer system 1000 further includes a read only memory (ROM) 1008 or other static storage device coupled to bus 1002 for storing static information and instructions for processor 1004. A storage device 1010, such as a magnetic disk, optical disk, or solid-state drive is provided and coupled to bus 1002 for storing information and instructions.

Computer system 1000, in some implementations, is coupled via bus ˜02 to a display 1012, such as a cathode ray tube (CRT), for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. This input device typically has two degrees of freedom in two axes, a first axis (e.g., x) and a second axis (e.g., y), that allows the device to specify positions in a plane.

In some applications, computer system 1000 implements the techniques described herein using customized hard-wired logic, one or more ASICs or FPGAs, firmware and/or program logic which in combination with the computer system causes or programs computer system 1000 to be a special-purpose machine. According to one implementation, the techniques herein are performed by computer system 1000 in response to processor 1004 executing one or more sequences of one or more instructions contained in main memory 1006. Such instructions are read into main memory 1006 from another storage medium, such as storage device 1010. Execution of the sequences of instructions contained in main memory 1006 causes processor 1004 to perform the process steps described herein. In alternative implementations, hard-wired circuitry is used in place of or in combination with software instructions.

The term “storage media” as used herein refers to any non-transitory media that store data and/or instructions that cause a machine to operate in a specific fashion. Such storage media includes non-volatile media and/or volatile media. Non-volatile media includes, for example, optical disks, magnetic disks, or solid-state drives, such as storage device 1010. Volatile media includes dynamic memory, such as main memory 1006. Common forms of storage media include, for example, a floppy disk, a flexible disk, hard disk, solid-state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge.

Storage media is distinct from transmission media. Transmission media participates in transferring information between storage media. For example, transmission media includes coaxial cables, copper wire and fiber optics, including the wires that comprise bus 1002. Transmission media can also take the form of acoustic or light waves, such as those generated during radio-wave and infra-red data communications.

In some applications, various forms of media are involved in carrying one or more sequences of one or more instructions to processor 1004 for execution. For example, the instructions are carried on a magnetic disk or solid-state drive of a remote computer. The remote computer can load the instructions into its dynamic memory and send the instructions over a telephone line using a modem. A modem local to computer system 1000 can receive the data on the telephone line and use an infra-red transmitter to convert the data to an infra-red signal. An infra-red detector can receive the data carried in the infra-red signal and appropriate circuitry can place the data on bus 1002. Bus 1002 carries the data to main memory 1006, from which processor 1004 retrieves and executes the instructions. The instructions received by main memory 1006 may optionally be stored on storage device 1010 either before or after execution by processor 1004.

Computer system 1000 also includes a communication interface 1018 coupled to bus 1002. Communication interface 1018 provides a two-way data communication coupling to a network link 1020 that is connected to a local network 1022. For example, communication interface 1018 is, in some implementations, an integrated services digital network (ISDN) card, cable modem, satellite modem, or a modem to provide a data communication connection to a corresponding type of telephone line. As another example, communication interface 1018 is a local area network (LAN) card to provide a data communication connection to a compatible LAN. Wireless links may also be implemented. In any such implementation, communication interface 1018 sends and receives electrical, electromagnetic or optical signals that carry digital data streams representing various types of information.

Network link 1020 typically provides data communication through one or more networks to other data devices. For example, network link 1020 provides a connection through local network 1022 to a host computer 1024 or to data equipment operated by an Internet Service Provider (ISP) 1026. ISP 1026 in turn provides data communication services through the world wide packet data communication network now commonly referred to as the “Internet” 1028. Local network 1022 and Internet 1028 both use electrical, electromagnetic or optical signals that carry digital data streams. The signals through the various networks and the signals on network link 1020 and through communication interface 1018, which carry the digital data to and from computer system 1000, are example forms of transmission media.

Computer system 1000 can send messages and receive data, including program code, through the network(s), network link 1020 and communication interface 1018. In the Internet example, a server 1030 might transmit a requested code for an application program through Internet 1028, ISP 1026, local network 1022 and communication interface 1018.

The received code is executed by processor 1004 as it is received, and/or stored in storage device 1010, or other non-volatile storage for later execution.

In the foregoing specification, implementations of the invention have been described with reference to numerous specific details that may vary from implementation to implementation. The specification and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction.

What is claimed is:

1. A method implemented on a computer system comprising:
executing a model of a physical system including a plurality of elements for a plurality of time steps such that, for at least a portion of the plurality of time steps, exchange of data between at least a portion of the plurality of elements is suppressed.

2. The method of claim 1, wherein the plurality of elements is grouped into a plurality of partitions; and
wherein the at least the portion of the plurality of elements are on edges of the plurality of partitions.

3. The method of claim 1, further comprising, for each time step of the at least the portion of the time steps and each element of the at least the portion of the plurality of elements:
estimating current flux data corresponding to past flux data obtained from a state of a neighboring element of the plurality of elements in a time step immediately preceding said each time step.

4. The method of claim 1, further comprising, for each time step of the at least the portion of the time steps and each element of the at least the portion of the plurality of elements:
estimating current flux data corresponding to past flux data obtained from states of a neighboring element of the plurality of elements in multiple time steps immediately preceding said each time step.

5. The method of claim 1, further comprising, for each time step of the at least the portion of the time steps and each element of the at least the portion of the plurality of elements:
estimating current flux data by extrapolating past flux data obtained from states of a neighboring element of the plurality of elements in multiple time steps immediately preceding said each time step.

6. The method of claim 1, further comprising, for each time step of the at least the portion of the time steps and each element of the at least the portion of the plurality of elements:
estimating current flux data by processing, using a machine learning model, past flux data obtained from a state of a neighboring element in a time step immediately preceding said each time step.

7. The method of claim 6, wherein the machine learning model is a neural network.

8. The method of claim 7, wherein the neural network is a deep neural network.

9. A method comprising:
providing, on a computer system, a model of a physical system including a plurality of elements each having one or more state variables;
for each time step of one or more first time steps:
obtaining, by the computer system, first flux data for a first element of the plurality of elements, the first flux data corresponding to the one or more state variables of one or more second elements of the plurality of elements;
processing, by the computer system, the one or more state variables of the first element and the first flux data according to the model; and
updating the one or more state variables according to the processing of the one or more state variables of the first element and the first flux data;
for a second time step subsequent to the one or more first time steps:
calculating, by the computer system, second flux data for the first element based on the first flux data from the one or more first time steps;
processing, by the computer system, the one or more state variables of the first element and the second flux data according to the model; and
updating, by the computer system, the one or more state variables of the first element according to the processing of the one or more state variables of the first element and the second flux data.

10. The method of claim 9, wherein calculating the second flux data comprises extrapolating the second flux data from the first flux data.

11. The method of claim 9, wherein calculating the second flux data comprises linearly extrapolating the second flux data from the first flux data.

12. The method of claim 9, wherein the one or more first time steps include at least two time steps.

13. The method of claim 9, wherein calculating the second flux data comprises calculating the second flux data based on the first flux data and the one or more state variables of the first element.

14. The method of claim 13, wherein the one or more state variables include first variables and second variables that are partial derivatives of the first variables.

15. The method of claim 13, wherein calculating the second flux data comprises processing the first flux data and the one or more state variables of the first element using a machine learning model.

16. The method of claim 15, wherein the machine learning model is a neural network.

17. The method of claim 16, wherein the neural network is a deep neural network including one or more hidden layers.

18. The method of claim 9, wherein the plurality of elements are divided into a plurality of partitions, each partition including a group of contiguous elements of the plurality of elements.

19. The method of claim 18, wherein the first element is on an edge of a partition of the plurality of partitions.

20. The method of claim 19, further comprising:
obtaining third flux data for a third element of the plurality of elements corresponding to the one or more state variables of one or more fourth elements of the plurality of elements, the third element and fourth element being in a same partition of the plurality of partitions and the third element not being an edge element of the same partition;
processing the one or more state variables of the third element and the third flux data according to the model; and
updating the one or more state variables of the third element according to the processing of the one or more state variables of the third element and the third flux data.

21. An apparatus comprising:
one or more processing devices;
one or more memory devices operably coupled to the one or more processing devices, the one or more memory devices storing executable code that, when executed by the one or more processing devices, causes the one or more processing devices to:
execute a model of a physical system including a plurality of elements for a plurality of time steps such that, for at least a portion of the plurality of time steps, exchange of data between at least a portion of the plurality of elements is suppressed.

22. The apparatus of claim 21, wherein the plurality of elements is grouped into a plurality of partitions; and
wherein the at least the portion of the plurality of elements are on edges of the plurality of partitions.

23. The apparatus of claim 21, wherein the executable code, when executed by the one or more processing devices, further causes the one or more processing devices to, for each time step of the at least the portion of the time steps and each element of the at least the portion of the plurality of elements:
estimate current flux data corresponding to past flux data obtained from a state of a neighboring element of the plurality of elements in a time step immediately preceding said each time step.

24. The apparatus of claim 21, wherein the executable code, when executed by the one or more processing devices, further causes the one or more processing devices to, for each time step of the at least the portion of the time steps and each element of the at least the portion of the plurality of elements:
estimate current flux data corresponding to past flux data obtained from states of a neighboring element of the plurality of elements in multiple time steps immediately preceding said each time step.

25. The apparatus of claim 21, wherein the executable code, when executed by the one or more processing devices, further causes the one or more processing devices to, for each time step of the at least the portion of the time steps and each element of the at least the portion of the plurality of elements:
estimate current flux data by extrapolating past flux data obtained from states of a neighboring element of the plurality of elements in multiple time steps immediately preceding said each time step.

26. The apparatus of claim 21, wherein the executable code, when executed by the one or more processing devices, further causes the one or more processing devices to, for each time step of the at least the portion of the time steps and each element of the at least the portion of the plurality of elements:
estimate current flux data by processing, using a machine learning model, past flux data obtained from a state of a neighboring element in a time step immediately preceding said each time step.
